(19) United States
(12) Patent Application Publication
(10) Pub. No.: US 2016/0197071 A1
(43) Pub. Date: Jul. 7, 2016

(54) INTEGRATED CIRCUIT DEVICE AND METHOD FOR FORMING THE SAME

(71) Applicant: MediaTek Inc., Hsin-Chu (TW)

(72) Inventors: Chao-Yang YEH, New Taipei City (TW); Yi-Feng CHEN, Xinpu Township (TW); Jia-Wei FANG, Hsinchu City (TW); Yao-Tsung HUANG, Kaohsiung City (TW); Ming-Cheng LEE, Zhubei City (TW)

(21) Appl. No.: 14/861,461

(22) Filed: Sep. 22, 2015

Related U.S. Application Data
(60) Provisional application No. 62/100,613, filed on Jan. 7, 2015.
(60) Provisional application No. 62/100,158, filed on Jan. 6, 2015.

(51) Int. Cl. H01L 27/08; H01L 49/02; H01L 21/283

(52) U.S. Cl. CPC H01L 27/0805; H01L 21/283; H01L 28/60

(57) ABSTRACT

The invention provides an integrated circuit device. The integrated circuit device includes a semiconductor substrate. An isolation structure is positioned in the semiconductor substrate. A first electrode and a second electrode are positioned on the semiconductor substrate and coupled to different voltage supplies. The first electrode laterally or parallelly overlaps the second electrode. The first electrode and the second electrode vertically overlap the isolation structure. As a result, leakage current is mitigated or eliminated so that the reliability and performance of the integrated circuit device are improved.

### CROSS REFERENCE TO RELATED APPLICATIONS

This application is based on, and claims priority of U.S. Provisional Application No. 62/100,158 filed on Jan. 6, 2015, and priority of U.S. Provisional Application No. 62/100,613 filed on Jan. 7, 2015 the entirety of which is incorporated by reference herein.

### BACKGROUND OF THE INVENTION

1. Field of the Invention

The present invention relates to an integrated circuit device, and in particular to an integrated circuit device with a decoupling capacitor and methods for forming the same.

2. Description of the Related Art

In an integrated circuit device, there may be a plurality of decoupling capacitors implemented therein. The use of these decoupling capacitors is for reducing undesirable circuit power noise and for solving the dynamic IR drops of the integrated circuit device. In general, the circuit structures of decoupling capacitors vary under different design requirements. One of the most common techniques is a metal-oxide-semiconductor (MOS) capacitor.

For instance, if a decoupling capacitor is a MOS capacitor, a gate of the MOS capacitor is coupled to a VDD voltage supply and source and drain electrodes of the MOS capacitor are coupled to a VSS voltage supply, or vice versa. Conventionally, the process of decoupling capacitors in an integrated circuit device is substantially the same as the process of core elements (such as transistors) in the integrated circuit device.

However, under advanced semiconductor processes, using MOS capacitors as decoupling capacitors leads to excessive leakage currents in the integrated circuit device. The unwanted leakage current worsens the performance of the integrated circuit device. As a result, it is difficult to further increase the reliability and quality of electronic products made therefrom.

Thus, there exists a need in the art for development of an integrated circuit device with a decoupling capacitor and methods for forming the same capable of mitigating or eliminating the aforementioned problems.

### BRIEF SUMMARY OF THE INVENTION

An embodiment of the invention provides an integrated circuit device comprising a semiconductor substrate. An isolation structure is positioned in the semiconductor substrate. A first electrode and a second electrode are positioned on the semiconductor substrate and coupled to different voltage supplies. The first electrode laterally or parallelly overlaps the second electrode. The first electrode and the second electrode vertically overlap the isolation structure.

An embodiment of the invention provides an integrated circuit device comprising a semiconductor substrate. An isolation structure is positioned in the semiconductor substrate. First electrodes are coupled to a first voltage supply. A second electrode is coupled to a second voltage supply different from the first voltage supply. The second electrode is laterally or parallelly positioned between the first electrodes. The first electrodes and the second electrode are separated and insulated from the semiconductor substrate by the isolation structure.

An embodiment of the invention provides a method for forming an integrated circuit device comprising providing a semiconductor substrate. An isolation structure is formed in the semiconductor substrate. A first electrode vertically overlapping the isolation structure is formed by a front-end-of-line process. A second electrode vertically overlapping the isolation structure is formed by a middle-end-of-line process. The first electrode and the second electrode are coupled to different voltage supplies, and laterally or parallelly overlap each other.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1C are cross-sectional views of various stages of a method for forming an integrated circuit device, in accordance with some embodiments of the disclosure.

FIG. 2 is a top view of an integrated circuit device, in accordance with some embodiments of the disclosure.

FIG. 3 is a cross-sectional view of an integrated circuit device, in accordance with some other embodiments of the disclosure.

FIG. 4 is a cross-sectional view of an integrated circuit device, in accordance with some other embodiments of the disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

Embodiments provide an integrated circuit device. The integrated circuit device comprises one or more decoupling capacitors on a semiconductor substrate. The decoupling capacitor is formed of two electrodes (such as a gate electrode layer and a bottommost metal layer) laterally or parallelly overlapping with each other. The two electrodes vertically overlap an isolation structure in the semiconductor substrate, and are electrically insulated from the semiconductor substrate by the isolation structure. Consequently, the integrated circuit device is free of leakage current that may occur between the semiconductor substrate and the gate electrode layer thereon. The reliability of the integrated circuit device is significantly improved.

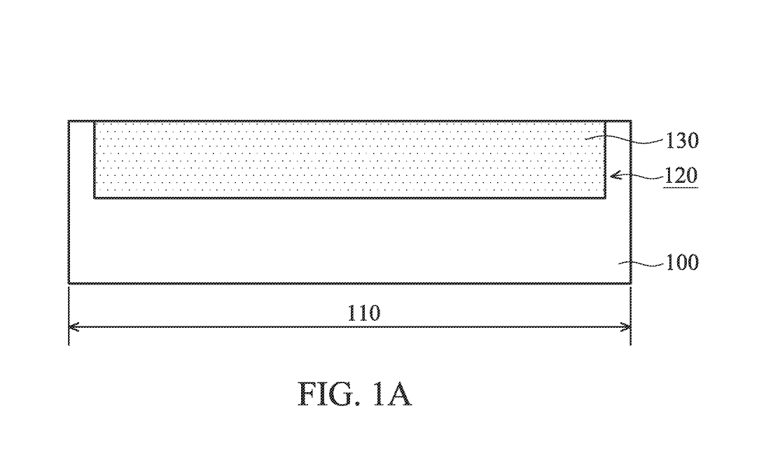

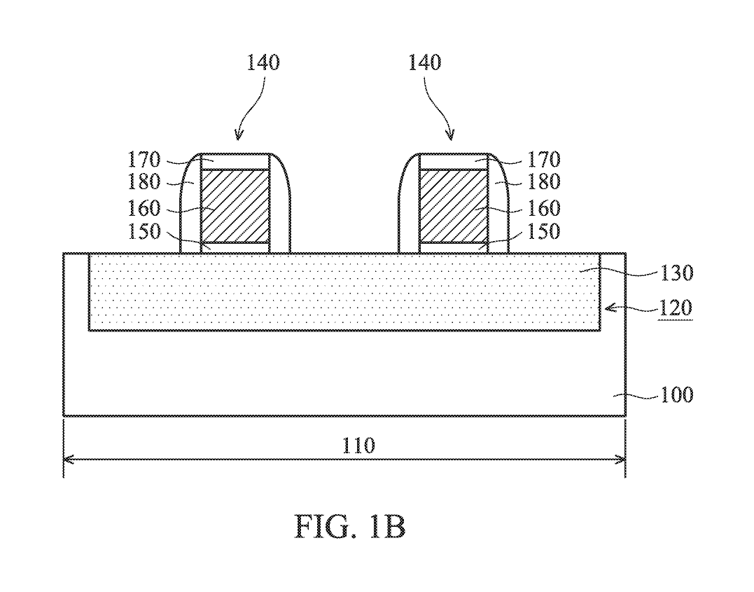

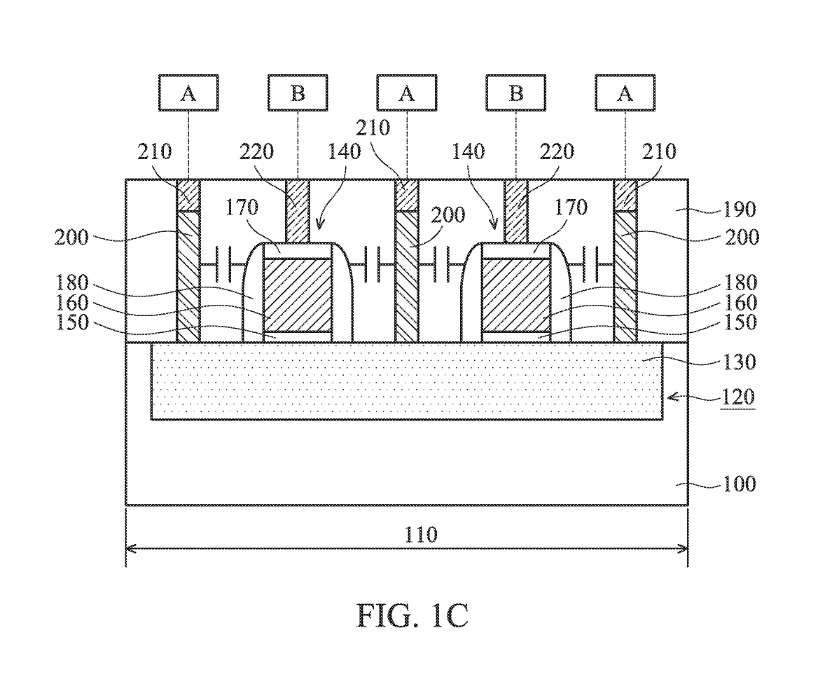

FIGS. 1A-1C are cross-sectional views of various stages of a method for forming an integrated circuit device, in accordance with some embodiments of the disclosure. Additional operations can be provided before, during, and/or after the stages described in FIGS. 1A-1C. Some of the stages that are described can be replaced or eliminated for different embodiments. Additional features can be added to the integrated circuit device. Some of the features described below can be replaced or eliminated for different embodiments.

As shown in FIG. 1A, a semiconductor substrate 100 is provided during front-end-of-line (FEOL) processes. In some embodiments, the semiconductor substrate 100 is a bulk semiconductor substrate such as a semiconductor wafer. For example, the semiconductor substrate 100 is a silicon wafer. The semiconductor substrate 100 may include silicon or another elementary semiconductor material such as germanium. In some other embodiments, the semiconductor substrate 100 includes a compound semiconductor. The compound semiconductor may include gallium arsenide, silicon carbide, indium arsenide, another suitable compound semiconductor, or a combination thereof. In some embodiments, the semiconductor substrate 100 includes a semiconductor-on-insulator (SOI) substrate.

The semiconductor substrate 100 comprises several cell regions. In some embodiments, the cell regions may have a side-by-side arrangement. Core or active elements (such as transistors) are configured to be formed in some of the cell regions (i.e. active regions). Passive elements (such as capacitors, resistors or the like) are configured to be formed in some other cell regions (i.e. non-active regions). To simplify the diagram, only a portion of a cell region 110 is depicted herein as an example. One or more decoupling capacitors are configured to be formed in the cell region 110. In some embodiments, the cell region 110 is a non-active region. In some other embodiments, the area of the non-active region in the cell region 110 is much greater than that of the active region in the cell region 110.

As shown in FIG. 1A, one or more recesses (trenches) 120 are formed in the semiconductor substrate 100. In some embodiments, one or more photolithography and etching processes are used to form the recesses 120. Afterward, a dielectric material layer is deposited in the recesses 120. As a result, one or more isolation structures 130 are formed in the semiconductor substrate 100. The isolation structures 130 are used to define active and non-active regions and electrically isolate various elements formed in and/or over the semiconductor substrate 100. In some embodiments, the isolation structures comprise shallow trench isolation (STI) structures, another suitable isolation structure, or a combination thereof.

In some embodiments, the dielectric material layer is deposited using a chemical vapor deposition (CVD) process, a spin-on process, another applicable process, or a combination thereof. In some embodiments, the dielectric material may comprise silicon oxide, silicon nitride, silicon oxynitride, low-K dielectric material, another suitable material, or a combination thereof.

In accordance with some embodiments of the disclosure, one or more fin structures are formed. Therefore, the integrated circuit device will comprise one or more fin field-effect transistors (FinFETs) as core elements. For example, multiple recesses or trenches (such as the recesses or trenches 120) are formed in the semiconductor substrate 100. As a result, multiple fin structures are formed between the recesses. The isolation structures 130 are formed in the recesses to cover or surround a lower portion of the fin structures.

Afterward, one or multiple gate stacks 140 are formed on the semiconductor substrate 100. In some embodiments, some of the gate stacks 140 are in direct contact with the semiconductor substrate 100 or the fin structures made of the semiconductor substrate 100. These gate stacks 140 are configured to be a portion of the core or active elements. Channel regions (not shown) are formed or defined in the semiconductor substrate 100 or the fin structures directly under these gate stacks 140. The channel regions may be used to provide a connecting path for carriers between the subsequently formed source/drain structures.

As shown in FIG. 1B, some of the gate stacks 140 are formed directly on the isolation structure 130 and are in physical contact with the isolation structure 130. These gate stacks 140 are configured to be a portion of passive elements (decoupling capacitors). No channel region is formed or defined directly under these gate stacks 140.

Each of the gate stacks 140 comprises a gate dielectric layer 150 and a gate electrode layer 160. The gate electrode layer 160 is positioned on the gate dielectric layer 150. In some embodiments, the gate dielectric layer 150 is made of silicon oxide, silicon nitride, silicon oxynitride, another suitable dielectric material, or a combination thereof. In some embodiments, the gate electrode layer 160 comprises polysilicon, a metal material, another suitable conductive material, or a combination thereof. In some embodiments, each of the gate stacks 140 further comprises a hard mask 170 on the gate electrode layer 160. The hard mask 170 may serve as an etching mask during the formation of the gate electrode layer 160 and may also protect the gate electrode layer 160 during subsequent processes.

In accordance with some embodiments, a gate dielectric material layer, a gate electrode material layer, and a hard mask layer are sequentially deposited on the semiconductor substrate 100. Each of the gate dielectric material layer, the gate electrode material layer, and the hard mask layer may be deposited using a chemical vapor deposition (CVD) process, an atomic layer deposition (ALD) process, a physical vapor deposition (PVD) process, another applicable process, or a combination thereof. Afterwards, a photolithography process and an etching process are performed to pattern the hard mask layer so as to form the hard mask 170. The gate dielectric material layer and the gate electrode material layer are then etched through the pattern defined in the hard mask 170. As a result, multiple gate stacks 140 comprising the gate dielectric layer 150, the gate electrode layer 160 and the hard mask 170 are formed.

In some embodiments, the gate stacks 140 that are configured to form active elements and passive elements are fabricated by the same step. In some other embodiments, the gate stacks 140 that are configured to form active elements and passive elements may be fabricated by different steps.

As shown in FIG. 1B, gate spacers 180 are formed on the sidewalls of the gate dielectric layer 150, the gate electrode layer 160 and the hard mask 170. In some embodiments, the gate spacers 180 are made of silicon nitride, silicon oxynitride, another suitable material, or a combination thereof. In some embodiments, a spacer material layer is deposited on the semiconductor substrate 100 and the gate stacks 140. Afterwards, an etching process is performed to partially remove the spacer material layer. As a result, portions of the spacer material layer remains on the sidewalls of the gate stacks 140 so as to form the gate spacers 180.

In some embodiments, source/drain structures (not shown) are formed in the semiconductor substrate 100 during the FEOL processes. For example, portions of the semiconductor substrate 100 are doped with one or more suitable dopants so as to form the source/drain structures. In some other embodiments, the source/drain structures may comprise epitaxially grown semiconductor materials (such as silicon germanium) doped with one or more suitable dopants. The source/drain structures are positioned on two opposite sides of the gate stacks 140 that are configured to form active elements. As a result, core or active elements (such as a metal-oxide-semiconductor field-effect transistor (MOSFET), a FinFET, or another suitable transistor) are formed in the integrated circuit device.

Afterward, an interconnection structure is formed on the semiconductor substrate 100 and the isolation structure 130 by multiple deposition processes, photolithography processes and etching processes. The interconnection structure may comprise an interlayer dielectric (ILD) layer, inter-metal dielectric (IMD) layers, metal layers, and contacts/vias. Recesses are formed in the dielectric layer and conductive materials are deposited in the recesses to form the metal layers or the vias. As a result, the metal layers and the vias are embedded in the ILD layer and the IMD layers. Some of the metal layers and the vias are electrically connected to the gate stacks 140 and the source/drain structures.

As shown in FIG. 1C, a dielectric layer 190 comprising the ILD layer is shown. The gate stacks 140 and the gate spacers 180 are buried in the dielectric layer 190. In some embodiments, the dielectric layer 190 is made of silicon oxide, silicon nitride, silicon oxynitride, low dielectric constant (low-K) material, other suitable materials, or a combination thereof. In some other embodiments, the dielectric layer 190 in the cell region 110 is made of high-K material. Examples of high-K dielectric material comprise hafnium oxide, zirconium oxide, aluminum oxide, another suitable high-K material, or a combination thereof. For instance, a dielectric material layer is formed on the semiconductor substrate 100 and the isolation structure 130. Some portions of the dielectric material layer in the cell region 110 are replaced by high-K material.

A bottommost metal (metal-zero, M0) layer 200 formed by middle-end-of-line (MEOL) processes is embedded in the dielectric layer 190. The M0 layer 200 extends along the gate stacks 140. In some embodiments, the M0 layer 200 is higher than the gate stacks 140. Some portions of the M0 layer 200 are positioned in the cell region 110 and vertically overlap the isolation structure 130. Some other portions of the M0 layer 200 are positioned in the active region and vertically overlap the source/drain structures. In some embodiments, the M0 layer 200 comprises copper, tungsten, aluminum, nickel, titanium, other suitable conductive materials, or a combination thereof.

Vias 210 and 220 formed by the MEOL processes are embedded in the dielectric layer 190. The vias 210 are positioned on the M0 layer 200. The vias 220 are positioned on the gate stacks 140. In some embodiments, the vias 210 laterally or parallelly overlap the vias 220. In some other embodiments, the vias 210 do not laterally or parallelly overlap the vias 220. In some embodiments, the vias 210 and 220 have a staggered arrangement. In some embodiments, the vias 210 and 220 comprise copper, tungsten, aluminum, nickel, titanium, other suitable conductive materials, or a combination thereof.

In accordance with some embodiments, the IMD layers, other metal layers and vias (not shown) are formed by back-end-of-line (BEOL) processes and are positioned on the dielectric layer 190 and the vias 210 and 220.

The vias 210 are electrically connected to a voltage supply A while the vias 220 are electrically connected to a voltage supply B that is different from the voltage supply A. In some embodiments, the voltage supply A is a VDD voltage supply and the voltage supply B is a VSS voltage supply. In some other embodiments, the voltage supply A is a VSS voltage supply and the voltage supply B is a VDD voltage supply. The M0 layer 200 is electrically connected to the voltage supply A through the vias 210. The gate electrode layer 160 is electrically connected to the voltage supply B through the vias 220. As a result, the M0 layer 200 and the gate electrode layer 160 are electrically coupled to different voltage supplies.

Since the M0 layer 200 and the gate electrode layer 160 of the gate stacks 140 laterally and parallelly overlap each other, one or more decoupling capacitors are constructed of the M0 layer 200 and the gate electrode layer 160. The gate electrode layer 160 forms first electrodes of the decoupling capacitors. The M0 layer 200 forms second electrodes of the decoupling capacitors. In some embodiments, the first electrodes and the second electrodes have an interlaced arrangement. In other words, one of the first electrodes is located between the second electrodes, and one of the second electrodes is located between the first electrodes.

In some embodiments, the M0 layer 200 and the gate stacks 140 have a wall-like structure. The overlapping area between the M0 layer 200 and the gate electrode layer 160 is increased. Consequently, the decoupling capacitance between the M0 layer 200 and the gate electrode layer 160 is improved. The decoupling capacitance in the cell region 110 is mainly provided by the M0 layer 200 and the gate electrode layer 160 of the gate stacks 140.

In some other embodiments, the decoupling capacitance in the cell region 110 is increased (such as about two or three times) as a result of the dielectric layer 190 made of high-K material. In some embodiments, each of the second electrodes (the M0 layer 200) has at least one via 210 formed thereon. In some other embodiments, one of the second electrodes has more than one via 210 formed thereon. Therefore, the decoupling capacitance in the cell region 110 is enhanced (such as about 20%). Alternatively, more than one second electrode may have a plurality of vias 210 formed thereon. In some embodiments, one or more conductive layers (such as an M1 layer or an M2 layer) are formed on the gate electrode layer 160 and the M0 layer 200 during the BEOL processes. The M1 or M2 layer may be electrically connected to the same voltage supply as the M0 layer 200 and vertically overlap the gate electrode layer 160. Alternatively, the M1 or M2 layer may be electrically connected to the same voltage supply as the gate electrode layer 160 and vertically overlap the M0 layer 200. Therefore, the decoupling capacitance in the cell region 110 is improved even further.

In particular, the gate electrode layer 160 in the cell region 110 is physically separated and electrically insulated from the semiconductor substrate 100 by the isolation structure 130. Therefore, no decoupling capacitor is formed between the gate electrode layer 160 and the semiconductor substrate 100. Namely, no capacitance is provided between the gate electrode layer 160 and the semiconductor substrate 100. As a result, leakage current between the gate electrode layer 160 and the semiconductor substrate 100 in the cell region 110 is mitigated or eliminated. In accordance with some embodiments, the aforementioned decoupling capacitor can be implemented in resistance-capacitance delay (RC delay) circuits.

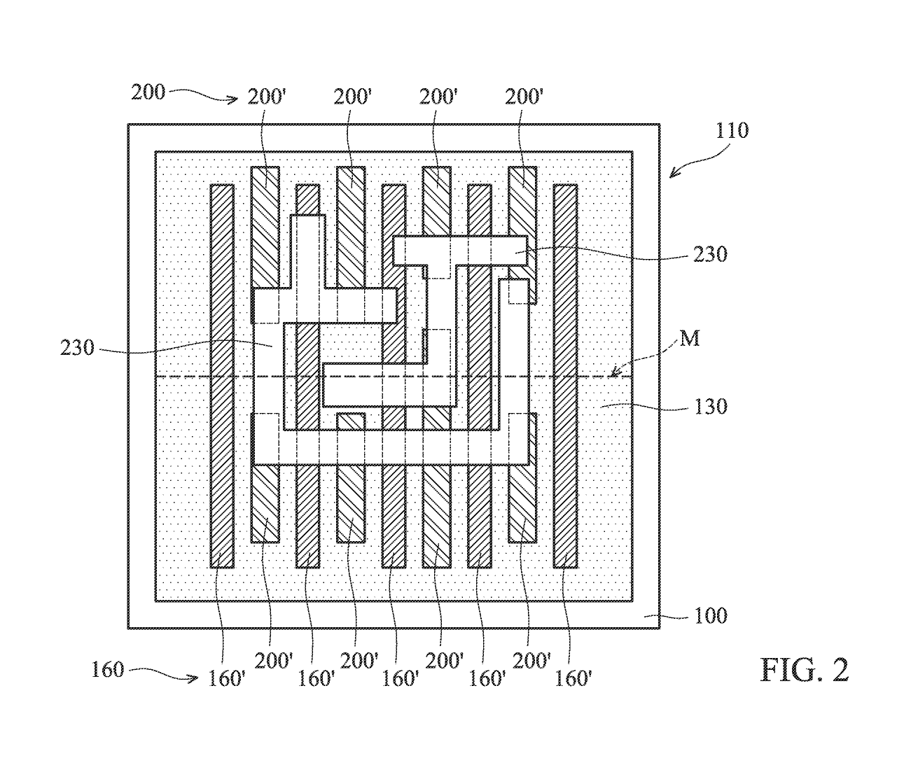

FIG. 2 is a top view of an integrated circuit device, in accordance with some embodiments of the disclosure. Elements in FIG. 2 that are the same as those in FIGS. 1A-1C are labeled with the same reference numbers as in FIGS. 1A-1C and are not described again for brevity. For the purpose of clarifying the relative position, only the isolation structure 130, the semiconductor substrate 100, the gate electrode layer 160, the M0 layer 200, and the M1 layer 230 are shown in FIG. 2. It should be realized that the gate electrode layer 160, the M0 layer 200, and the M1 layer 220 may have other configurations.

As shown in FIG. 2, one isolation structure 130 is formed in the semiconductor substrate 100 in the cell region 110. The gate electrode layer 160 and the M0 layer 200 are formed on the isolation structure 130. The M0 layer 200 is electrically connected to a first voltage supply while the gate electrode layer 160 is electrically connected to a second voltage supply that is different from the first voltage supply. Since the M0 layer 200 and the gate electrode layer 160 laterally and parallelly overlap each other, many decoupling capacitors are formed on the isolation structure 130. In some embodiments, the gate electrode layer 160 and the M0 layer 200 are completely isolated from the semiconductor substrate 100 by the isolation structure 130. In some other embodiments, one or more portions of the gate electrode layer 160 or the M0 layer 200 are connected to the semiconductor substrate 100.

The gate electrode layer 160 comprises strip portions 160′ corresponding to the gate stacks. The strip portions 160′ extend across a middle line M of the cell region 110. The M0 layer 200 comprises shorter strip portions 200′ in comparison with the strip portions 160′. In some embodiments, the strip portions 200′ are positioned on two sides of the middle line M. In some other embodiments, one or more of the strip portions 200′ extend across the middle line M. The strip portions 200′ extend from a first end of the strip portions 160′ toward a second end opposite the first end. In some embodiments, the strip portions 200′ extend from the first or second end of the strip portions 160′ across the middle portion between the first end and the second end.

The strip portions 200′ substantially extend along the strip portions 160′. In other word, the strip portions 200′ and the strip portions 160′ extend along the same direction. In some embodiments, the extending length of the strip portions 160′ is greater than the extending length of the strip portions 200′. The strip portions 160′ and 200′ have a staggered arrangement. In some embodiments, two strip portions 200′, which align with each other, are positioned between two strip portions 160′. In some other embodiments, one strip portion 200′ or more than two strip portions 200′, which align with each other, are positioned between two strip portions 160′.

In some embodiments, there are five strip portions 160′ of the gate electrode layer 160 in the cell region 110. In some other embodiments, the number of the strip portions 160′ in the cell region 110 can be four or less than four (such as three or two). The size of the cell region 110 for decoupling capacitors is greatly reduced. Therefore, the performance of an integrated circuit device with high integrated density can be enhanced.

As shown in FIG. 2, the M1 layer 230 is formed on the gate electrode layer 160 and the M0 layer 200. The M1 layer 230 is electrically connected to the gate electrode layer 160 or the M0 layer 200 through vias. In some embodiments, the M1 layer 230 vertically overlaps the gate electrode layer 160 and/or the M0 layer 200. In some embodiments, the M1 layer 230 extends across the middle line M and vertically overlaps the gate electrode layer 160 and the M0 layer 200. When the M1 layer 230 and the gate electrode layer 160 are electrically connected to different voltage supplies, supplementary decoupling capacitance may be provided between the M1 layer 230 and the gate electrode layer 160. When the M1 layer 230 and the M0 layer 200 are electrically connected to different voltage supplies, supplementary decoupling capacitance may be provided between the M1 layer 230 and the M0 layer 200. In some embodiments, the overlapping area between the M1 layer 230 and the M0 layer 200 is greater than that between the M1 layer 230 and the gate electrode layer 160.

In some embodiments, some of the strip portions 160′ are electrically connected to each other by a conductive layer formed on a lower portion of the cell region 110 (a lower side of the middle line M). In some embodiments, the decoupling capacitance in an upper portion of the cell region 110 (on an upper side of the middle line M) is larger than that in the lower portion of the cell region 110.

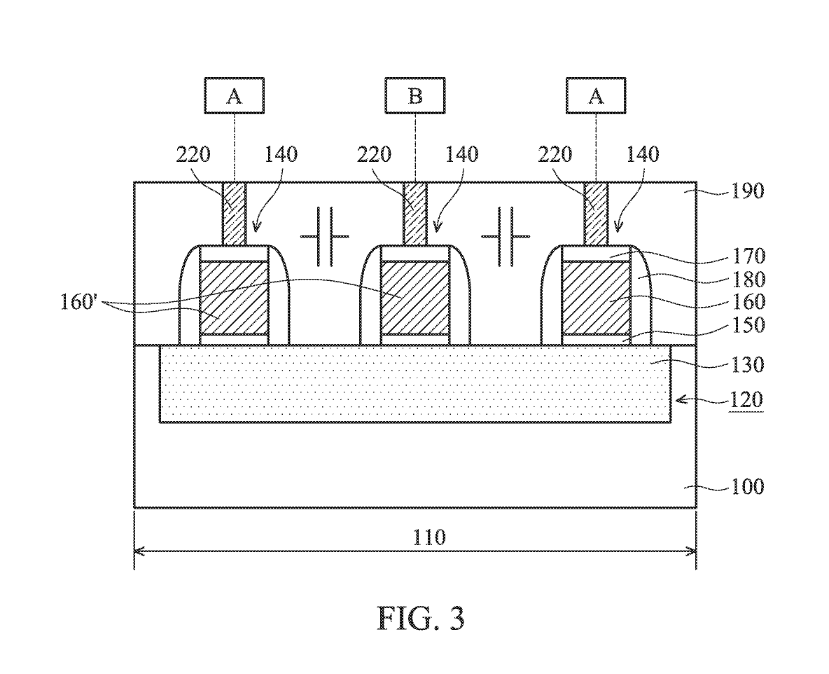

FIG. 3 is a cross-sectional view of an integrated circuit device, in accordance with some other embodiments of the disclosure. Elements in FIG. 3 that are the same as those in FIGS. 1A-1C and FIG. 2 are labeled with the same reference numbers as in FIGS. 1A-1C and FIG. 2, and are not described again for brevity.

As shown in FIG. 3, one gate stack 140 is electrically connected to the voltage supply A while another gate stack 140 is electrically connected to the voltage supply B. In some embodiments, no M0 layer 200 is positioned between the two gate stacks 140. Consequently, one or more decoupling capacitors are constructed of the gate electrode layer 160 of two gate stacks 140 (the two strip portions 160′). The two strip portions 160′ form a first electrode and a second electrode of the decoupling capacitor.

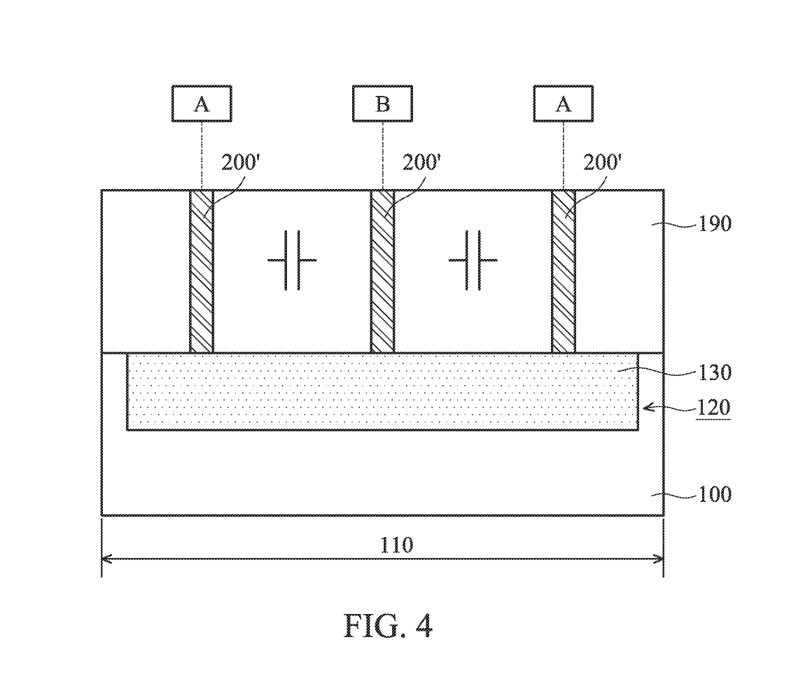

FIG. 4 is a cross-sectional view of an integrated circuit device, in accordance with some other embodiments of the disclosure. Elements in FIG. 4 that are the same as those in FIGS. 1A-1C and FIG. 2 are labeled with the same reference numbers as in FIGS. 1A-1C and FIG. 2, and are not described again for brevity.

As shown in FIG. 4, one strip portions 200′ of the M0 layer 200 is electrically connected to the voltage supply A while another strip portions 200′ is electrically connected to the voltage supply B. In some embodiments, no gate stack 140 is positioned between the two strip portions 200′. Consequently, one or more decoupling capacitors are constructed of two strip portions 200′ of the M0 layer 200. The two strip portions 200′ form a first electrode and a second electrode of the decoupling capacitor.

In accordance with some embodiments of the disclosure, an integrated circuit device can comprise many decoupling capacitors that have different structures as shown in FIG. 1C, FIG. 2 and FIG. 3. The actual structure and number of decoupling capacitors are determined by design requirements.

Embodiments provide an integrated circuit device. The integrated circuit device comprises one or more decoupling capacitors on a semiconductor substrate. The decoupling capacitor is constructed of first and second electrodes. The first and second electrodes may be a gate electrode layer formed by FEOL processes and a bottommost metal layer formed by MEOL processes. Alternatively, the first and second electrodes may be formed of a gate electrode layer or a bottommost metal layer. The first and second electrodes laterally and/or parallelly overlap each other. The first and second electrodes vertically overlap an isolation structure in the semiconductor substrate, and are electrically insulated from the semiconductor substrate by the isolation structure. In other words, substantially no active region is defined or formed under the decoupling capacitors. As a result, leakage current is significantly prevented. The reliability and quality of the electronic products made from the integrated circuit device is greatly improved.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. An integrated circuit device, comprising:
a semiconductor substrate;
an isolation structure in the semiconductor substrate; and
a first electrode and a second electrode on the semiconductor substrate and coupled to different voltage supplies, wherein the first electrode laterally overlaps and the second electrode are parallel.

2. The integrated circuit device as claimed in claim 1, wherein the first electrode is made of a gate electrode layer, and the second electrode is made of a bottommost metal layer.

3. The integrated circuit device as claimed in claim 1, wherein the first electrode and the second electrode are made of a gate electrode layer.

4. The integrated circuit device as claimed in claim 1, wherein the first electrode and the second electrode are made of a bottommost metal layer.

5. The integrated circuit device as claimed in claim 1, wherein the first electrode and the second electrode extend on the isolation structure along the same direction.

6. The integrated circuit device as claimed in claim 5, wherein an extending length of the first electrode is greater than an extending length of the second electrode.

7. The integrated circuit device as claimed in claim 1, further comprising a dielectric layer between the first electrode and the second electrode, wherein the dielectric layer covers the isolation structure.

8. The integrated circuit device as claimed in claim 7, wherein the dielectric layer comprises a high-K dielectric material.

9. The integrated circuit device as claimed in claim 7, further comprising at least one via embedded in the dielectric layer, wherein the at least one via is electrically connected to the first electrode or the second electrode.

10. The integrated circuit device as claimed in claim 1, further comprising one or more conductive layers disposed on the first electrode and the second electrode and vertically overlapping the first electrode and/or the second electrode.

11. An integrated circuit device, comprising:
a semiconductor substrate;
an isolation structure in the semiconductor substrate;
a plurality of first electrodes coupled to a first voltage supply; and
a second electrode coupled to a second voltage supply different from the first voltage supply, wherein the second electrode is laterally positioned between the plurality of first electrodes, and wherein the plurality of first electrodes and the second electrode are separated and insulated from the semiconductor substrate by the isolation structure.

12. The integrated circuit device as claimed in claim 11, wherein the plurality of first electrodes and the second electrode comprise different materials.

13. The integrated circuit device as claimed in claim 11, wherein the plurality of first electrodes and the second electrode comprise the same material.

14. The integrated circuit device as claimed in claim 11, wherein one of the plurality of first electrodes has a first end and a second end, and wherein the second electrode extends from the first end toward the second end.

15. The integrated circuit device as claimed in claim 14, wherein the second electrode extends across a middle portion between the first end and the second end.

16. The integrated circuit device as claimed in claim 11, further comprising a dielectric layer on the isolation structure, wherein the plurality of first electrodes and the second electrode are embedded in the dielectric layer.

17. The integrated circuit device as claimed in claim 16, wherein the dielectric layer comprises a high-K dielectric material.

18. The integrated circuit device as claimed in claim 16, further comprising at least one conductive layer on the dielectric layer and electrically coupled to the first voltage supply or the second voltage supply.

19. A method for forming an integrated circuit device, comprising:
providing a semiconductor substrate;
forming an isolation structure in the semiconductor substrate;
forming a first electrode over the isolation structure by a front-end-of-line process; and
forming a second electrode over the isolation structure by a middle-end-of-line process, wherein the first electrode and the second electrode are parallel and are coupled to different voltage supplies.

20. The method for forming an integrated circuit device as claimed in claim 19, wherein the first electrode and the second electrode are separated and insulated from the semiconductor substrate by the isolation structure.

21. The method for forming an integrated circuit device as claimed in claim 19, further comprising forming a dielectric layer after the formation of the first electrode, wherein the first electrode is embedded in the dielectric layer.

22. The method for forming an integrated circuit device as claimed in claim 21, wherein the formation of the dielectric layer comprises depositing a high-K dielectric material on the isolation structure.

23. The method for forming an integrated circuit device as claimed in claim 21, wherein the formation of the second electrode comprises:
forming a recess in the dielectric layer; and
depositing a conductive material in the recess to form the second electrode.

24. The method for forming an integrated circuit device as claimed in claim 19, wherein the first electrode laterally overlaps the second electrode.

25. The method for forming an integrated circuit device as claimed in claim 19, wherein the first electrode and the second electrode vertically overlap the isolation structure.

26. The integrated circuit device as claimed in claim 1, wherein the first electrode laterally overlaps the second electrode.

27. The integrated circuit device as claimed in claim 1, wherein the first electrode and the second electrode vertically overlap the isolation structure.
